(19) United States
(12) Patent Application Publication
(10) Pub. No.: US 2017/0301842 A1
(43) Pub. Date: Oct. 19, 2017

(54) LIGHT EMITTING PACKAGE STRUCTURE

(71) Applicant: TEAM EXPERT MANAGEMENT CONSULTING SERVICE, LTD., Taoyuan City (TW)

(72) Inventor: Lee-Sheng YEN, Taoyuan City (TW)

(73) Assignee: Team Expert Management Consulting Service, Ltd.

(21) Appl. No.: 15/200,650

(22) Filed: Jul. 1, 2016

(30) Foreign Application Priority Data
Apr. 18, 2016 (TW) 105205378

(51) Int. Cl. H01L 33/62; H01L 33/50; H01L 33/56; H01L 33/60

(52) U.S. Cl. CPC H01L 33/62; H01L 33/60; H01L 33/502; H01L 33/56

(57) ABSTRACT

A light emitting package structure is provided, which includes: a lead frame having at least two leads with a gap formed therebetween; a light emitting element crossing the gap and bonded to the at least two leads; and a plurality of conductive elements electrically connected with the light emitting element and the leads. Since the weight and stress of the light emitting element are borne by the leads, the stress can be evenly distributed to thereby prevent tilted disposing of the light emitting package structure on a circuit board or a tombstoning effect and cause the light emitting package structure to obtain a preferred light pattern.

### BACKGROUND

### 1. Technical Field

The present disclosure relates to package structures, and, more particularly, to a light emitting package structure.

### 2. Description of Related Art

Along with the rapid development of electronic industries, electronic products are reduced in size and developed in function toward high performance, high functionality and high speed. Light emitting diodes (LEDs) have advantages of long lifetime, small volume, high shock resistance and low power consumption, and, therefore, have been widely applied in various electronic products to meet lighting requirements.

Generally, LEDs are divided into vertical, face-up and flip-chip types. A vertical type LED has two electrodes positioned at a light emitting side and an opposite mounting side thereof, respectively. The mounting side is a side attached to a carrier. A face-up type LED has both electrodes positioned at the light emitting side thereof. A flip-chip type LED has both electrodes positioned at the mounting side thereof.

FIG. 1A is a schematic cross-sectional view of a conventional face-up type LED package structure 1. The LED package structure 1 has a lead frame 10, an LED chip 11 disposed on the lead frame 10, a reflecting element 12 embedded in the lead frame 10, and a silicone 13 formed in the reflecting element 12 to encapsulate the LED chip 11.

The lead frame 10 has a plurality of leads 10a, 10b, and the LED chip 11 is disposed on one of the leads 10a, 10b.

The LED chip 11 has a light emitting side 11a and an opposite mounting side 11b. The light emitting side 11a of the LED chip 11 has electrodes 110 connected to the leads 10a through bonding wires 15, and the mounting side 11b of the LED chip 11 is bonded to the lead 10b through a bonding layer 14 such as an adhesive.

The reflecting element 12 is embedded in the lead frame 10, and has a bowl-shaped inclined surface 12a surrounding the LED chip 11. Through the bowl-shaped inclined surface 12a, the LED chip 11 emits light upward (in an arrow of the drawing). The leads 10a, 10b extend and protrude from a lower side of the reflecting element 12.

The silicone 13 is formed in the reflecting element 12 to encapsulate the LED chip 11 and the bonding wires 15. Further, a phosphor layer (not shown) can be formed on a surface of the silicone 13, or the silicone 13 can be mixed with phosphor powder.

However, the lead frame 10 of the conventional LED package structure 1 has a long heat conduction path, a high thermal resistance and a large thickness of about 0.2 mm, which adversely affect the heat dissipation effect and hinder miniaturization of the LED package structure 1.

FIG. 1B is a schematic cross-sectional view of a conventional epoxy molding compound (EMC) face-up type LED package structure F. The LED package structure 1′ has a lead frame 10′, an LED chip 11 disposed on the lead frame 10′, a reflecting element 12 disposed on the lead frame 10′, and an epoxy resin 13′ formed in the reflecting element 12 to encapsulate the LED chip 11.

The lead frame 10′ has a chip mounting pad 100 and a plurality of leads 101, and the LED chip 11 is disposed on the chip mounting pad 100 of the lead frame 10′.

The LED chip 11 has a light emitting side 11a and an opposite mounting side 11b. The light emitting side 11a of the LED chip 11 has electrodes 110 connected to the leads 101 through bonding wires 15, and the mounting side 11b of the LED chip 11 is attached to the chip mounting pad 100 through a bonding layer 14 such as an adhesive. Referring to FIG. 1B′, the chip mounting pad 100 carries the entire LED chip 11 and has a layout size greater than that of the leads 101.

The reflecting element 12 is disposed on upper and lower sides of the lead frame 10, and has a bowl-shaped inclined surface 12a surrounding the LED chip 11. Through the bowl-shaped inclined surface 12a, the LED chip 11 emits light upward (in an arrow of the drawing). Further, lower surfaces of the chip mounting pad 100 and the leads 101 are exposed from a lower side of the reflecting element 12.

The epoxy resin 13′ is formed in the reflecting element 12 to encapsulate the LED chip 11 and the bonding wires 15. Further, a phosphor layer (not shown) can be formed on a surface of the epoxy resin 13′, or the epoxy resin 13′ can be mixed with phosphor powder.

However, since the LED chip 11 is completely disposed on the chip mounting pad 100, the load and stress experienced by the chip mounting pad 100 are greater than those experienced by the leads 101, resulting in an uneven stress distribution. Therefore, when a surface mount technology (SMT) process is subsequently performed to dispose the LED package structure 1′ on a circuit board (not shown), a solder material bonded to the lower sides of the chip mounting pad 100 and the leads 101a has a poor coplanarity, thus causing tilted disposing of the LED package structure 1′ on the circuit board.

Further, since the rectangular layout area of the chip mounting pad 100 is greater than that of the leads 101, during the subsequent SMT process, the solder portion bonded to the lower side of the chip mounting pad 100 is greater in volume than the solder portion bonded to the lower side of the leads 101, thereby causing significant volume and height differences and poor coplanarity between the solder portions and hence tilted disposing of the LED package structure 1′ on the circuit board.

Furthermore, the lead frame 10′ is quite thick, and the distance between the chip mounting pad 100 and the leads 101 is difficult to be reduced. As such, miniaturization of the LED package structure 1′ is adversely affected.

Therefore, how to overcome the above-described drawbacks has become critical.

### SUMMARY

In view of the above-described drawbacks, the present disclosure provides a light emitting package structure, which comprises: a lead frame having at least two leads with a gap formed therebetween; a light emitting element having a light emitting side and a mounting side opposite to the light emitting side, wherein the mounting side of the light emitting element crosses over the gap and is bonded to the leads; and a plurality of conductive elements electrically connected with the light emitting element and the leads.

In an embodiment, the lead frame has two leads with the gap formed between the two leads.

In an embodiment, the leads have an identical layout area.

In an embodiment, the leads have an identical layout shape.

In an embodiment, the light emitting side has a plurality of electrodes.

In an embodiment, the mounting side has a plurality of electrodes.

In an embodiment, the conductive elements are bonding wires. In another embodiment, the bonding wires are connected to the leads in a cross manner.

In an embodiment, the package structure further comprises a reflecting element disposed on the lead frame and surrounding the light emitting element.

In an embodiment, the package structure further comprises an encapsulant encapsulating the light emitting element and the conductive elements.

In an embodiment, the package structure further comprises a phosphor layer formed on the encapsulant. In another embodiment, the encapsulant comprises phosphor powder.

In an embodiment, a phosphor layer is formed on a surface of the light emitting element.

In an embodiment, the package structure further comprises an insulating layer bonded to the lead frame, with a portion of a surface of the lead frame exposed from the insulating layer.

According to the present disclosure, since the mounting side of the light emitting element is bonded to the leads, the weight and stress of the light emitting element are borne by the leads. As such, the stress is evenly distributed. Consequently, during a subsequent SMT process, a solder material bonded to lower sides of the leads has a good coplanarity, thereby preventing tilted disposing of the light emitting package structure on a circuit board or a tombstoning effect. Tombstoning refers to lifting of an element on one end after an infrared or hot air reflow soldering process due to different curing rates that are caused by a difference in solderabilty or heat dissipation rate between metal joints at two ends of the element and bonding pads of a circuit board.

Further, since the leads have an identical or similar layout area, the solder portions bonded to the lower sides of the two leads have substantially identical volume and height. Hence, the solder material has a good coplanarity, thereby preventing tilted disposing of the light emitting package structure on a circuit board.

Furthermore, the lead frame has an extremely short heat conduction path, an extremely low thermal resistance and a very thin thickness. As such, the light emitting package structure obtains an excellent heat dissipation effect and meets the miniaturization requirement.

In addition, the light emitting element disposed over the leads is easily disposed in the middle of the light emitting package structure so as to allow light emitted from the light emitting element to be evenly distributed. Therefore, the light emitting package structure obtains a preferred light pattern.

### BRIEF DESCRIPTION OF DRAWINGS

FIG. 1A is a schematic cross-sectional view of a conventional LED package structure;

FIG. 1B is a schematic cross-sectional view of another conventional LED package structure;

FIG. 1B′ is a lower view of a lead frame of the LED package structure of FIG. 1B;

FIG. 2A is a schematic cross-sectional view of a light emitting package structure according to a first embodiment of the present disclosure;

FIG. 2A′ is a lower view of a lead frame of the light emitting package structure according to the present disclosure;

FIG. 2B shows another embodiment of FIG. 2A;

FIG. 3 is a schematic cross-sectional view of a light emitting package structure according to a second embodiment of the present disclosure; and

FIG. 3′ shows another embodiment of FIG. 3.

### DETAILED DESCRIPTIONS

The following illustrative embodiments are provided to illustrate the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first,” “second,” “on,” “a,” etc. are merely for illustrative purposes and should not be construed to limit the scope of the present disclosure.

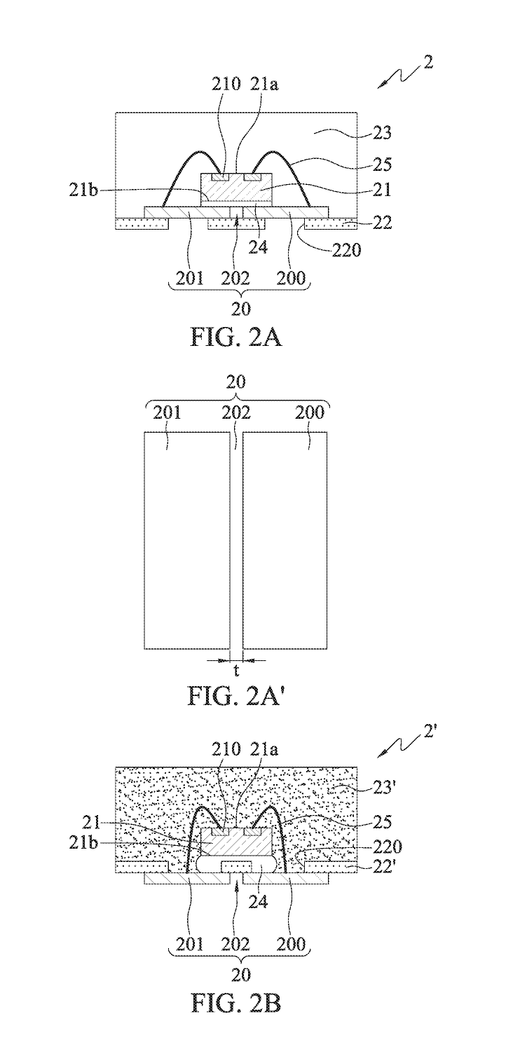

FIG. 2A is a schematic cross-sectional view of a light emitting package structure 2 according to a first embodiment of the present disclosure. The light emitting package structure 2 has a lead frame 20, a light emitting element 21 disposed on the lead frame 20, a plurality of conductive elements 25 electrically connected with the light emitting element 21 and the lead frame 20, and an encapsulant 23 for on the lead frame 20 and encapsulating the light emitting element 21 and the conductive elements 25.

The lead frame 20 has two sheet-shaped leads 200, 201 separated from each other and having an identical or similar layout size.

In an embodiment, the two leads 200, 201 have a rectangular layout shape, and a gap 202 is formed between the two leads 200, 201.

The light emitting element 21 is a face-up type LED, which has a light emitting side 21a having two electrodes 210, and a mounting side 21b opposite to the light emitting side 21a and bonded to the two leads 200, 201 through a bonding layer 24 such as an adhesive.

In an embodiment, the light emitting element 21 is an LED die or an LED package. In another embodiment, a phosphor layer is coated on a surface of an LED chip to form an LED package that is generally referred to as a white chip. The mounting side 21b of the light emitting element 21 crosses over the gap 202 and is bonded to the two leads 200, 201.

The conductive elements 25 are bonding wires for connecting the electrodes 210 of the light emitting element 21 and the leads 200, 201 of the lead frame 20.

In an embodiment, each of the bonding wires is connected to a corresponding one of the leads 200, 201 on the same side. For example, the bonding wire on the left side is connected to the lead 201 on the left side. In another embodiment, the bonding wires are connected to the leads 200, 201 in a cross manner. For example, the bonding wire on the left side is connected to the lead 200 on the right side. As such, the bonding wires cross one another, without coming into contact.

In an embodiment, a phosphor layer (not shown) is further formed on the encapsulant 23 or coated on a surface of the light emitting element 21. In another embodiment, referring to a light emitting package structure 2′ of FIG. 2B, the encapsulant 23′ of the light emitting package structure 2′ is mixed with phosphor powder.

Further, the encapsulant 23 can have, but not limited to, a rectangular shape of FIG. 2A, an arc shape having a mirror surface, etc.

The light emitting package structure 2 further has an insulating layer 22 bonded to the lead frame 20, with a portion of a surface of the lead frame 20 exposed from the insulating layer 22.

In an embodiment, the insulating layer 22 is a solder mask, which is formed on a lower side of the lead frame 20 and has a plurality of openings 220 exposing a portion of the leads 200, 201. Further, a solder material (not shown) can be bonded to the exposed portion of the leads 200, 201. The openings 220 of the insulating layer 22 facilitate to control the exposed portion of the leads 200, 201.

In another embodiment, referring to FIG. 2B, an insulating layer 22′ is formed on an upper side of the lead frame 20 and has a plurality of openings 220. As such, upper surfaces of the leads 200, 201 are partially exposed through the openings 220 for the conductive elements 25 to be bonded therewith. Further, lower surfaces of the leads 200, 201 are exposed from the encapsulant 23′ for a solder material (not shown) to be bonded therewith.

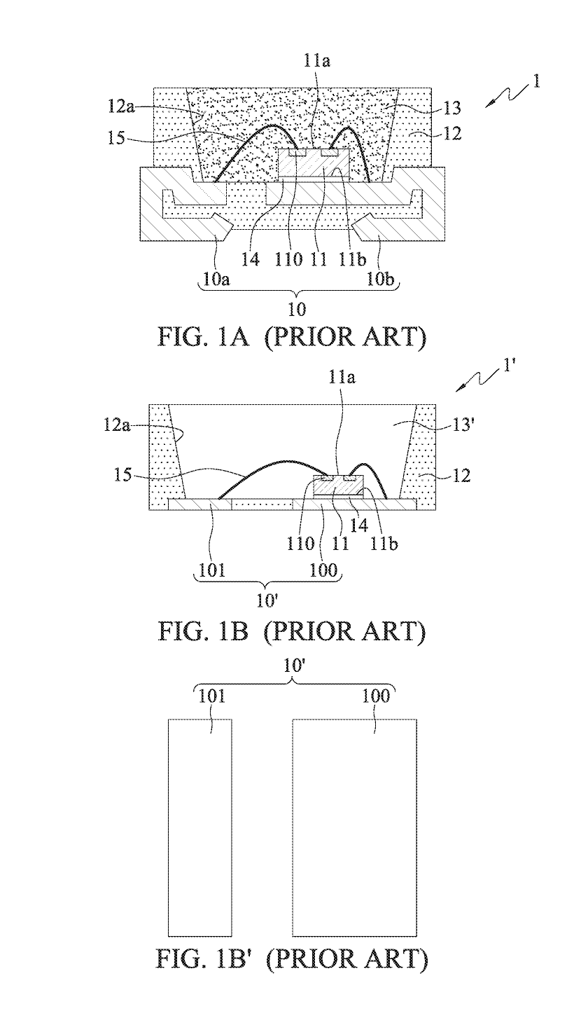

In another embodiment, the light emitting package structure 2, 2′ further has a reflecting element (referring to the reflecting element 12 of FIGS. 1A and 1B) disposed on the upper side of the lead frame 20 and having a bowl-shaped structure surrounding the light emitting element 21. As such, the light emitting element 21 emits light upward through the inclined surface of the reflecting element.

Furthermore, the light emitting element 21 is of a wire-bonding type, which has a low cost. The larger the contact area between the mounting side 21b of the light emitting element 21 and the leads 200, 201 is, the better the heat dissipation effect becomes. Therefore, referring to FIG. 2A′, the width t of the gap 202 should be as small as possible.

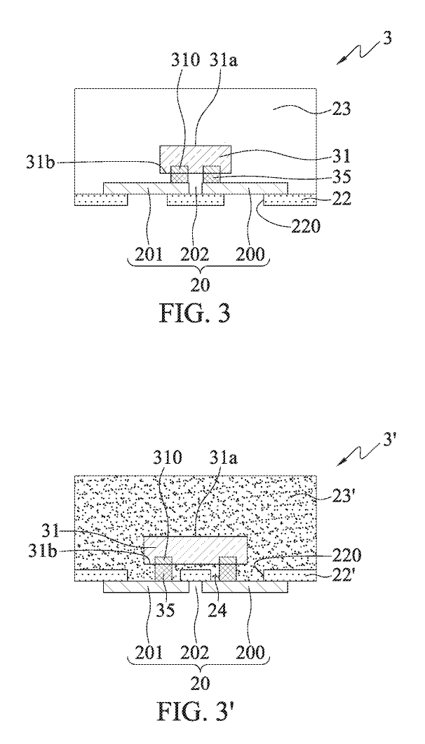

FIG. 3 is a schematic cross-sectional view of a light emitting package structure 3 according to a second embodiment of the present disclosure. The second embodiment differs from the first embodiment in the type of the light emitting element.

Different from FIG. 2A, the light emitting element 31 of the light emitting package structure 3 of FIG. 3 is a flip-chip type LED, which has a light emitting side 31a, and an mounting side 31b opposite to the light emitting side 31a and having two electrodes 310 bonded to the leads 200, 201 through conductive elements 35.

In an embodiment, the conductive elements 35 are made of solder, eutectic bonding structures, silver paste, conductive adhesive and so on.

FIG. 3′ shows a light emitting package structure 3′ according to another embodiment of the present disclosure. FIG. 3′ differs from FIG. 2B in the light emitting element 31 and the conductive elements 35.

According to the light emitting package structure 2, 2′, 3, 3′ of the present disclosure, since the mounting side 21b, 31b of the light emitting element 21, 31 is bonded to the two leads 200, 201, the weight and stress of the light emitting element 21, 31 are born by the two leads 200, 201. As such, the stress is evenly distributed. Consequently, during a subsequent SMT process, a solder material (not shown) bonded to the lower sides of the leads 200, 201 has a good coplanarity, thereby preventing tilted disposing of the light emitting package structure 2, 2′, 3, 3′ on a circuit board or a tombstoning effect.

Further, since the two leads 200, 201 have an identical or similar layout area, during the subsequent SMT process, the solder portions (not shown) bonded to the lower sides of the two leads 200, 201 have substantially identical volume and height and hence good coplanarity so as to prevent tilted disposing of the light emitting package structure 2, 2′, 3, 3′ on a circuit board.

Furthermore, the leads 200, 201 of the lead frame 20 are rectangular sheets and have an extremely short heat conduction path, an extremely low thermal resistance and a very small thickness (about 0.045 mm). As such, the light emitting package structure 2, 2′, 3, 3′ obtains an excellent heat dissipation effect and meets the miniaturization requirement.

In addition, the light emitting element 21, 31 disposed over the two leads 200, 201 is easily disposed in the middle of the light emitting package structure 2, 2′, 3, 3′ so as to allow light emitted from the light emitting side 21a, 31a of the light emitting element 21, 31 to be evenly distributed. Therefore, the light emitting package structure 2, 2′, 3, 3′ obtains a preferred light pattern.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of the present disclosure defined by the appended claims.

1. A light emitting package structure, comprising:
a lead frame having at least two leads with a gap formed between the at least two leads;
a light emitting element having a light emitting side and a mounting side opposite to the light emitting side, wherein the mounting side of the light emitting element crosses over the gap and is bonded to the leads;
a plurality of conductive elements electrically connected with the light emitting element and the leads; and
an insulating layer bonded to the lead frame, the insulating layer including one or more openings that expose one or more surfaces of the lead frame.

2. The light emitting package structure of claim 1, wherein the leads have an identical layout area.

3. The light emitting package structure of claim 1, wherein the leads have an identical layout shape.

4. The light emitting package structure of claim 1, further comprising a plurality of electrodes disposed on the light emitting side.

5. The light emitting package structure of claim 1, further comprising a plurality of electrodes disposed on the mounting side.

6. The light emitting package structure of claim 1, wherein the conductive elements are bonding wires.

7. The light emitting package structure of claim 6, wherein the bonding wires are connected to the leads in a cross manner.

8. The light emitting package structure of claim 1, further comprising a reflecting element disposed on the lead frame.

9. The light emitting package structure of claim 8, wherein the reflecting element surrounds the light emitting element.

10. The light emitting package structure of claim 1, further comprising an encapsulant encapsulating the light emitting element and the conductive elements.

11. The light emitting package structure of claim 10, further comprising a phosphor layer formed on the encapsulant.

12. The light emitting package structure of claim 10, wherein the encapsulant comprises phosphor powder.

13. The light emitting package structure of claim 1, further comprising a phosphor layer formed on a surface of the light emitting element.

14-15. (canceled)

16. The light emitting package structure of claim 1, wherein the lead frame has exactly two leads with the gap formed between the two leads.
